(19) United States
(12) Patent Application Publication
(10) Pub. No.: US 2019/0214627 A1
(43) Pub. Date: Jul. 11, 2019

(54) Apparatus and Method of Treating a Lithium-Ion-Battery Part

(71) Applicant: Winsky Technology Hong Kong Limited, Shatin (HK)

(72) Inventors: Zhi Tan, Shenzhen (CN); YanFang Zhang, Shenzhen (CN); WenTao Yu, Shenzhen (CN)

(73) Assignee: Winsky Technology Hong Kong Limited

(21) Appl. No.: 15/867,197

(22) Filed: Jan. 10, 2018

(51) Int. Cl. H01M 4/04; H01M 2/14; C23C 16/50; C23C 16/40; C23C 16/34; C23C 16/32; C23C 16/06; C23C 14/08; C23C 14/06; C23C 14/14; C23C 14/24; C23C 14/35

(52) U.S. Cl. CPC H01M 4/0426; C23C 14/35; H01M 2/145; H01M 4/0428; C23C 16/50; C23C 16/404; C23C 16/34; C23C 16/32; C23C 16/06; C23C 14/082; C23C 14/0641; C23C 14/0635; C23C 14/14; C23C 14/24; H01M 4/0404

(57) ABSTRACT

An apparatus (100) for treating a lithium-ion battery part, such as an electrode (212), is disclosed as including deposition devices (203, 204, 205, 206) for depositing lithium onto the battery part by physical vapour deposition and/or chemical vapour deposition. A method of treating a lithium-ion battery part is disclosed as including providing a lithium-ion battery part, and depositing lithium onto said component by physical vapour deposition and/or chemical vapour deposition.

This invention relates to an apparatus and a method of treating lithium-ion battery parts, including, but not limited to, positive electrodes, negative electrodes, separators, copper foils and aluminium foils.

### BACKGROUND OF THE INVENTION

With the development of lithium-ion batteries, more and more research has been carried out in the hope of increasing the electric capacity and life of such batteries. It is known that addition/deposition of lithium monomers, lithium oxides and/or lithium-containing metal alloys onto the negative electrodes of such batteries are effective in increasing the electric capacity and life of such batteries. The existing lithium-filling methods carried out on negative electrodes of lithium-ion batteries include spraying lithium powder or sticking a piece of lithium tape on the negative electrodes. The former method suffers from inconsistent effect, non-compactness and non-continuousness; whereas for the latter method, as existing lithium tapes are of a thickness of 20 to 30 μm, such are too thick as they occupy too much space in the lithium-ion batteries.

It is thus an object of the present invention to provide an apparatus and a method of treating a lithium-ion battery part in which the aforesaid shortcomings are mitigated or at least to provide a useful alternative to the trade and public.

### SUMMARY OF THE INVENTION

According to a first aspect of the present invention, there is provided an apparatus for treating a lithium-ion battery part, including means for depositing lithium onto said battery part by physical vapour deposition and/or chemical vapour deposition.

According to a second aspect of the present invention, there is provided a method of treating a lithium-ion battery part, including (a) providing a lithium-ion battery part, and (b) depositing lithium onto said component by physical vapour deposition and/or chemical vapour deposition.

### BRIEF DESCRIPTION OF THE DRAWINGS

An embodiment of the present invention will now be described, by way of example only, with reference to the accompanying drawings, in which:

FIG. 1 shows a front view of an apparatus for treating a lithium-ion battery part according to an embodiment of the present invention; and

FIG. 2 shows a schematic structural view of part of the apparatus of FIG. 1.

### DETAILED DESCRIPTION OF THE EMBODIMENT

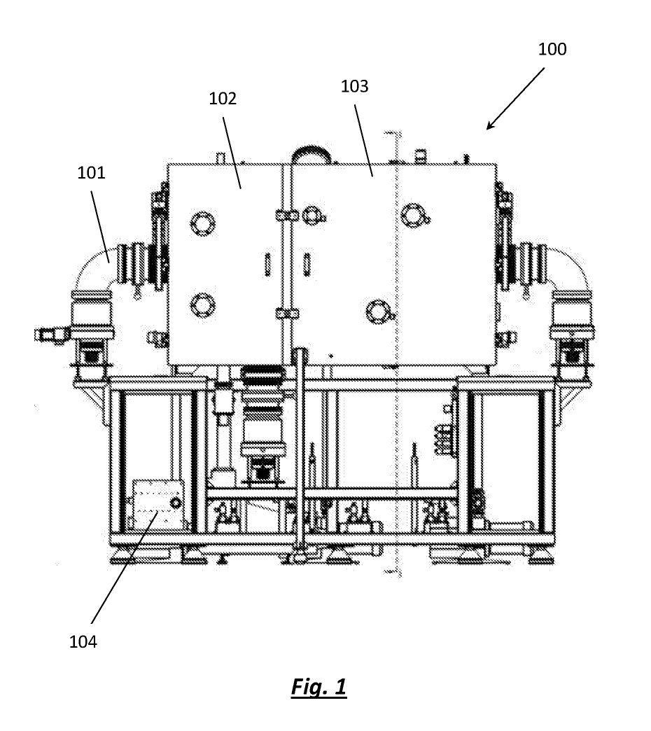

An apparatus for treating a lithium-ion battery part according to an embodiment of the present invention is shown in FIG. 1, and generally designated as 100. The apparatus 100 includes a vacuum pumping assembly 101, a workpiece feeding and collection chamber 102, a vacuum system chamber 103, and a power transmission system 104.

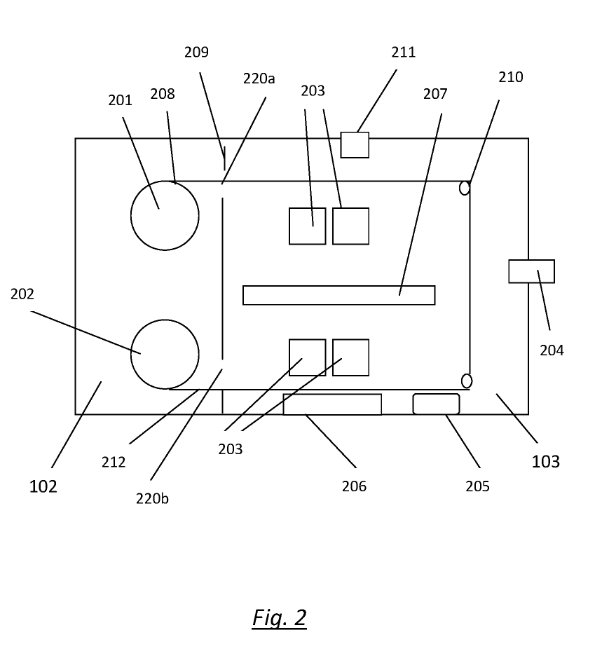

As shown in FIG. 2, the workpiece feeding and collection chamber 102 and the vacuum system chamber 103 are separated from each other by a heat shielding system 209 apart from two channels 220a, 220b through which a workpiece (e.g. an electrode 212) may pass. The vacuum system chamber 103 contains a cylindrical workpiece feeder 201 around which the workpiece (e.g. electrode 212) is wound. Upon operation of the power transmission system 104 in one operation mode, the workpiece feeder 201 rotates around its central longitudinal axis in the clockwise direction (in the sense of FIG. 2), and the electrode 212 is unwound from the workpiece feeder 201, and is fed through the channel 220a into the vacuum system chamber 103 for treatment. After treatment in the vacuum system chamber 103, the electrode 212 passes through the channel 220b and is wound around a cylindrical workpiece collector 202, which is also operated by the power transmission system 104 to rotate around its central longitudinal axis in the clockwise direction (again in the sense of FIG. 2). The workpiece feeding and collection chamber 102 also contains a biasing system 208 for providing a biasing voltage, to be discussed below.

The vacuum system chamber 103 includes magnetron sputtering systems 203, a chemical vapour deposition system 204, an arc discharge system 205, an ion-beam and resistance type evapouration coating system 206, a heating system 207, a workpiece cooling system 210, and a coating thickness monitoring system 211.

In operation, the workpiece (e.g. the electrode 212) is fed from the workpiece feeder 201 through the channel 220a into the vacuum system chamber 103 to undergo magnetron sputtering by the magnetron sputtering systems 203, and/or chemical vapour deposition by the chemical vapour deposition system 204, and/or arc discharge by the arc discharge system 205, and/or evapouration coating by the ion-beam and resistance type vapouration coating system 206. After undergoing such treatment process(es), the workpiece is conveyed through the channel 220b and wound around the workpiece collector 202 for collection purposes.

If necessary or desirable, it is possible to set the apparatus 100 to operate in another operation mode such that after winding of the electrode 212 onto the workpiece collector 202, the workpiece collector 202 is set to rotate in the counter-clockwise direction (in the sense of FIG. 2) to feed the electrode 212 through the channel 220b into the vacuum system chamber 103 for treatment again, and then conveyed through the channel 220a to be wound around the workpiece feeder 201 (which also rotates in the counter-clockwise direction) to collect the thus treated electrode 212. The apparatus 100 may thus be set to move the electrode 212 through the vacuum system chamber 103 for treatment, to and fro between the workpiece feeder 201 and the workpiece collector 202. Put another way, by changing the direction of rotation of the workpiece feeder 201 and the workpiece collector 202, the workpiece feeder 201 may act as a workpiece collector and the workpiece collector 202 may also act as a workpiece feeder 201, thus also allowing continuous treatment of the workpiece (e.g. electrode 212) by the apparatus 100 and method according to the present invention.

The apparatus 100 may be connected, upstream and/or downstream, with other equipment for the production of lithium-ion batteries, to form a fully-automated or partly-automated continuous lithium-ion battery production line, or a fully-automated or partly-automated vacuum type production system. Such other equipment may include cloth spraying, rolling, punching, winding, casing insertion, and/or liquid injecting machines.

Tests have been conducted to analyze the relevant characteristics of lithium-ion battery parts treated by the apparatus 100 and the method according to the present invention. In particular, negative electrodes of lithium-ion battery were produced by placing conventional negative electrodes into the workpiece feeding and collection chamber 102. The vacuum pumping assembly 101 was activated to reduce the pressure in the workpiece feeding and collection chamber 102 and vacuum system chamber 103 to not more than 5.0×10⁻³ Pa. The apparatus 100 was then pre-heated by the heating system 207 to 100° C. The power transmission system 104 was activated to feed the negative electrode through the channel 220a into the vacuum system chamber 103 to be treated by the magnetron sputtering systems 203, in which the magnetron sputtering negative electrode power was set at 2 kW. During the magnetron sputtering process, a biasing voltage of −150 V was set. After treatment in the vacuum system chamber 103, the treated negative electrode was wound around the workpiece collector 202.

The negative electrode workpiece treated as discussed in the immediately preceding paragraph was used for forming soft package lithium-ion batteries for testing purposes. In the tests, LiCoO₂ was used as the positive electrode, to provide consistency. A total of eight battery samples were produced. Samples 1 to 4 were conventional lithium-ion batteries, in which the positive electrodes were made of LiCoO₂ and the negative electrodes were conventional negative electrodes. Samples 5 to 8 include negative electrodes treated as discussed in the immediately preceding paragraph. In particular, such negative electrodes were conventional negative electrodes (as those used in forming Samples 1 to 4) further treated as discussed in the immediately preceding paragraph. The positive electrodes of Samples 5 to 8 were also made of LiCoO₂, as in the case of Samples 1 to 4. All other parameters of Samples 1 to 8 were identical.

Tables 1 and 2 below show relevant testing results of Samples 1 to 4 and Samples 5 to 8 respectively:

TABLE 1

| | First Time | First Time | |
|---|---|---|---|
| | Charging | Discharging | First Cycle |
| Sample | Capacity | Capacity | Efficiency |
| 1 | 1260.7 mAh | 1124.0 mAh | 89.2% |
| 2 | 1257.5 mAh | 1131.5 mAh | 90.0% |
| 3 | 1261.9 mAh | 1139.1 mAh | 90.3% |
| 4 | 1258.7 mAh | 1132.2 mAh | 90.0% |
| Average Value | 1259.7 mAh | 1131.7 mAh | 89.8% |

TABLE 2

| | First Time | First Time | |
|---|---|---|---|
| | Charging | Discharging | First Cycle |
| Sample | Capacity | Capacity | Efficiency |
| 5 | 1324.9 mAh | 1181.7 mAh | 89.2% |
| 6 | 1284.0 mAh | 1176.2 mAh | 91.6% |
| 7 | 1289.7 mAh | 1174.7 mAh | 91.1% |
| 8 | 1295.6 mAh | 1176.5 mAh | 90.8% |
| Average Value | 1298.6 mAh | 1177.3 mAh | 90.7% |

It can be seen from the foregoing test results that:
(a) the average capacity of the soft package lithium-ion batteries with negative electrodes treated according to the present invention is higher than that of the soft package lithium-ion batteries with conventional negative electrodes by around 3.9%, and
(b) the average first cycle efficiency of the soft package lithium-ion batteries with negative electrodes treated according to the present invention is higher than the soft package lithium-ion batteries with conventional negative electrodes by around 0.9%.

It was also found that as compared with Samples 1 to 4, Samples 5 to 8 exhibit the advantages/improvements of having a smoother surface, with no black stains, thus mitigating the lithium-release problem.

It was also found that lithium was deposited onto the negative electrode by a depth of up to 100 μm and of a width of up to 2000 mm.

Although the invention has thus far been discussed in the context of treating negative electrodes of lithium-ion batteries, it is envisaged that:
(a) the invention may be carried out on other parts of lithium-ion batteries, e.g. positive electrodes, separators, copper foils and aluminium foils;
(b) deposition of lithium onto lithium-ion battery parts according to the present invention may be carried out by chemical vapour deposition, either in place of or in addition to, physical vapour deposition;
(c) the physical vapour deposition methods which may be carried out according to the present invention include vacuum evaporation coating, magnetron sputtering, re-sputtering, radio frequency (RF) sputtering, electric arc sputtering, and ion coating;
(d) the chemical vapour deposition which may be carried out according to the present invention include plasma-assisted chemical vapour deposition (PACVD), plasma-enhanced chemical vapour deposition (PECVD), high temperature chemical vapour deposition, and low temperature chemical vapour deposition; and
(e) lithium may be deposited on the lithium-ion battery parts in the form of lithium monomers, lithium ions, lithium oxides, lithium nitrides, lithium carbides, lithium-containing compounds, and lithium-containing metal alloys.

It should be understood that the above only illustrates an example whereby the present invention may be carried out, and that various modifications and/or alterations may be made thereto without departing from the spirit of the invention. It should also be understood that various features of the invention which are, for brevity, described in the context of a single embodiment, may also be provided separately or in any appropriate sub-combinations.

1. An apparatus for treating a lithium-ion battery part, including means for depositing lithium onto said battery part by physical vapour deposition and/or chemical vapour deposition.

2. An apparatus according to claim 1, wherein said battery part includes a positive electrode, a negative electrode, a separator, a copper foil and an aluminium foil.

3. An apparatus according to claim 1, wherein said physical vapour deposition includes at least one of vacuum evaporation coating, magnetron sputtering, re-sputtering, radio frequency (RF) sputtering, electric arc sputtering, and ion coating.

4. An apparatus according to claim 1, wherein said chemical vapour deposition includes at least one of plasma-assisted chemical vapour deposition (PACVD), plasma-enhanced chemical vapour deposition (PECVD), high temperature chemical vapour deposition, and low temperature chemical vapour deposition.

5. An apparatus according to claim 1, wherein said apparatus is adapted to deposit at least one of lithium monomers, lithium ions, lithium oxides, lithium nitrides, lithium carbides, lithium-containing compounds, and lithium-containing metal alloys onto said battery part.

6. An apparatus according to claim 1, wherein said apparatus is adapted to deposit lithium onto said battery part by a depth of up to 100 μm.

7. An apparatus according to claim 1, wherein said apparatus is adapted to deposit lithium onto said battery part of a width of up to 2000 mm.

8. An apparatus according to claim 1, further including a vacuuming system, a heating system, an ion bombardment system, and/or a cooling system.

9. An apparatus according to claim 1, further including a workpiece feeder and a workpiece collector, wherein said apparatus is operable in a first mode in which said battery part is movable from said workpiece feeder to said workpiece collector and a second mode in which said battery part is movable from said workpiece collector to said workpiece feeder.

10. A method of treating a lithium-ion battery part, including:
(a) providing a lithium-ion battery part, and
(b) depositing lithium onto said component by physical vapour deposition and/or chemical vapour deposition.

11. A method according to claim 10, wherein said lithium-ion battery part includes a positive electrode, a negative electrode, a separator, a copper foil and an aluminium foil.

12. A method according to claim 10, wherein said physical vapour deposition includes at least one of vacuum evaporation coating, magnetron sputtering, re-sputtering, radio frequency (RF) sputtering, electric arc sputtering, and ion coating.

13. A method according to claim 10, wherein said chemical vapour deposition includes at least one of plasma-assisted chemical vapour deposition (PACVD), plasma-enhanced chemical vapour deposition (PECVD), high temperature chemical vapour deposition, and low temperature chemical vapour deposition.

14. A method according to claim 10, wherein said step (b) includes depositing at least one of lithium monomers, lithium ions, lithium oxides, lithium nitrides, lithium carbides, lithium-containing compounds, and lithium-containing metal alloys onto said battery part.

15. A method according to claim 10, wherein lithium is deposited onto said battery part by a depth of up to 100 μm.

16. A method according to claim 10, wherein lithium is deposited onto said battery part of a width of up to 2000 mm.

17. A method according to claim 10, further including selectively moving said battery part from a workpiece feeder to a workpiece collector and moving said battery part from said workpiece collector to said workpiece feeder.
